(19) United States
(12) Patent Application Publication
(10) Pub. No.: US 2021/0358856 A1
(43) Pub. Date: Nov. 18, 2021

(54) METHOD FOR FABRICATING SEMICONDUCTOR DEVICE

(71) Applicant: SK hynix Inc., Gyeonggi-do (KR)

(72) Inventors: Jung Nam KIM, Gyeonggi-do (KR); Jin Gyu PARK, Gyeonggi-do (KR); Il Sup JIN, Gyeonggi-do (KR); Min Ho HA, Gyeonggi-do (KR)

(21) Appl. No.: 16/998,403

(22) Filed: Aug. 20, 2020

(30) Foreign Application Priority Data
May 13, 2020 (KR) 10-2020-0056991

(51) Int. Cl. H01L 23/532; H01L 21/762

(52) U.S. Cl. CPC H01L 23/53295; H01L 21/76254; H01L 21/76243; H01L 21/76224

(57) ABSTRACT

A method for fabricating a semiconductor device includes forming a low-k dielectric layer, forming a pattern by etching the low-k dielectric layer, and implanting a carbon-containing material into a surface of the pattern.

### CROSS-REFERENCE TO RELATED APPLICATIONS

The present application claims priority to Korean Patent Application No. 10-2020-0056991, filed on May 13, 2020, which is incorporated herein by reference in its entirety.

### BACKGROUND

### 1. Field

Various embodiments of the present invention relate generally to a semiconductor device manufacturing method and, more particularly, to a method for fabricating a semiconductor device including a carbon-containing dielectric layer.

### 2. Description of the Related Art

As semiconductor devices become more highly integrated, the width and contact area of metal lines decreases, which gradually increases the resistance of the metal lines as well as their contact resistance. Also, the gap between metal lines and contact plugs becomes narrower, which increases the parasitic capacitance caused by a dielectric layer between the metal lines.

Heretofore, to address these problems, a dielectric layer having a low dielectric constant may be applied between the metal lines, however, there are still problems such as an increase in a dielectric constant and a decrease in Young's modulus.

### SUMMARY

Various embodiments of the present invention are directed to a method for fabricating a semiconductor device with improved characteristics and reliability.

In accordance with an embodiment of the present invention, a method for fabricating a semiconductor device is provided which includes: forming a low-k dielectric layer; forming a pattern by etching the low-k dielectric layer; and implanting a carbon-containing material into a surface of the pattern.

In accordance with another embodiment of the present invention, a method for fabricating a semiconductor device is provided which includes: forming a low-k dielectric layer containing carbon; forming a trench by performing a first etching of the low-k dielectric layer; implanting a carbon-containing material into a surface of the trench; and forming a via by performing a second etching of the low-k dielectric layer on a bottom surface of the trench.

In accordance with yet another embodiment of the present invention, a method for fabricating a semiconductor device is provided which includes: forming a dielectric layer; implanting a carbon-containing material into the dielectric layer; forming a trench by a first etching of the dielectric layer containing carbon; and forming a via by a second etching of the carbon-containing dielectric layer on a bottom surface of the trench.

In accordance with still another embodiment of the present invention, a semiconductor device is provided which includes: a first conductive layer formed over a substrate; a low-k dielectric layer including a trench and a via that are formed over the first conductive layer; a second conductive layer buried in the trench and the via; and a carbon implantation region formed on a surface of the trench of the second conductive layer in contact with the second conductive layer.

In accordance with still another embodiment of the present invention, a semiconductor device is provided which includes: a low-k dielectric layer formed over a substrate; an opening formed in the low-k dielectric layer by etching using a hard mask; and a carbon recovery region formed in the low-k dielectric by implanting a carbon-containing material into a surface region of the low-k dielectric layer pattern that is exposed by the opening.

These and other features and advantages of the present invention will become apparent to those skilled in the art to which the present invention belongs or pertains from the detailed description of specific embodiments in conjunction with the following drawings.

### BRIEF DESCRIPTION OF THE DRAWINGS

FIGS. 1A to 1F are cross-sectional views illustrating a method for fabricating a semiconductor device in accordance with an embodiment of the present invention.

FIGS. 2A to 2G are cross-sectional views illustrating a method for fabricating a semiconductor device in accordance with another embodiment of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

It will be further understood that when an element is referred to as being “connected to”, or “coupled to” another element, it may be directly on, connected to, or coupled to the other element, or one or more intervening elements may be present. Furthermore, the connection/coupling may not be limited to a physical connection but may also include a non-physical connection, e.g., a wireless connection.

In addition, it will also be understood that when an element is referred to as being “between” two elements, it may be the only element between the two elements, or one or more intervening elements may also be present.

When a first element is referred to as being “over” a second element, it not only refers to a case where the first element is formed directly on the second element but also a case where a third element exists between the first element and the second element.

It should be understood that the drawings are simplified schematic illustrations of the described devices and may not include well known details.

It should also be noted that features present in one embodiment may be used with one or more features of another embodiment without departing from the scope of the invention.

It is further noted, that in the various drawings, like reference numbers designate like elements.

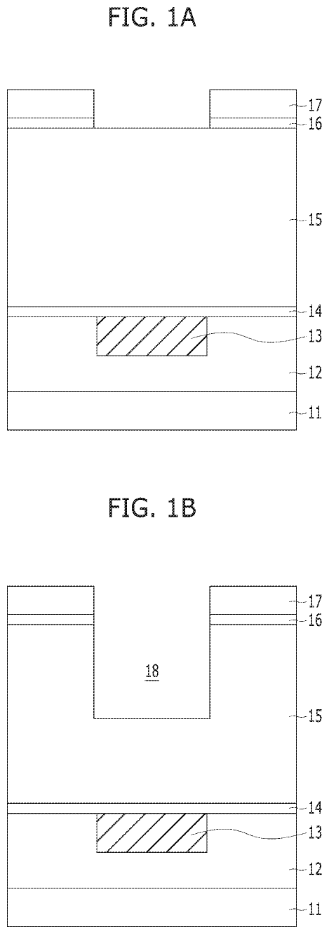

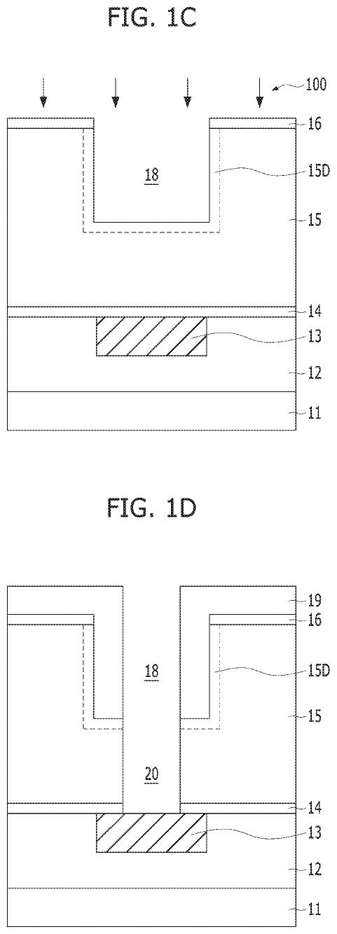

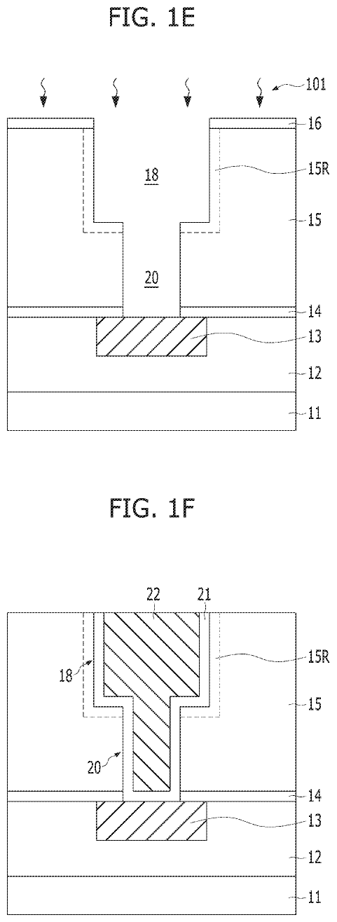

FIGS. 1A to 1F are cross-sectional views illustrating a method for fabricating a semiconductor device in accordance with an embodiment of the present invention.

Referring now to FIG. 1A, a first dielectric layer 12 in which a first metal line 13 is buried may be formed over a semiconductor substrate 11.

The semiconductor substrate 11 may be a semiconductor substrate in which a lower structure (not shown), such as a gate, a bit line, and a capacitor, is formed. The semiconductor substrate 11 may be formed of a material containing silicon. The semiconductor substrate 11 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The semiconductor substrate 11 may include a group ITIN semiconductor substrate, for example, a compound semiconductor substrate such as GaAs. The semiconductor substrate 11 may include a Silicon On Insulator (SOI) substrate.

The first dielectric layer 12 may be formed of one among a low-k material including silicon oxide, silicon nitride or silicon carbon and boron.

The first metal line 13 may include a conductive material. The first metal line 13 may include a metal material. The first metal line 13 may include, for example, tungsten, copper or aluminum.

Subsequently, an etch stop layer 14 may be formed over the first dielectric layer 12 including the first metal line 13. The etch stop layer 14 may also serve as a barrier to prevent diffusion of the metal of the first metal line 13 into a second dielectric layer 15. The etch stop layer 14 may include, for example, silicon nitride or silicon carbon.

Subsequently, the second dielectric layer 15 may be formed over the etch stop layer 14. The second dielectric layer 15 may be formed directly on the etch stop layer 14. The second dielectric layer 15 may be a dielectric layer having a low dielectric constant (i.e., a low-k dielectric layer). The second dielectric layer 15 may be a dielectric material having a lower dielectric constant than silicon oxide (SiO₂), and preferably a material whose dielectric constant is approximately 3.5 or less. The second dielectric layer 15 may be a low-k dielectric layer containing carbon. The second dielectric layer 15 may be an organosilicate glass (OSG) containing approximately 15% to 30% carbon, but the carbon content may not be limited thereto. The second dielectric layer 15 may be, for example, SiCOH. SiCOH is a mixture of Si—C—O—H, and SiCOH is a material having a characteristic that its dielectric constant decreases as the film contains more hydrogen (H) or carbon (C), which are atoms having a small electrical polarizability.

According to another embodiment of the present invention, the second dielectric layer 15 may include a low-k dielectric layer having a low dielectric constant by forming silicon oxide over the etch stop layer 14 and then implanting a carbon-containing material into the silicon oxide. For example, the second dielectric layer 15 may include a low-k dielectric layer which is formed by forming TEOS (Tetra Ethyl Ortho Silicate) over the etch stop layer 14, and then implanting a carbon-containing material into the TEOS. For example, the second dielectric layer 15 may include TEOS containing approximately 15% to 40% carbon, but the carbon content may not be limited thereto.

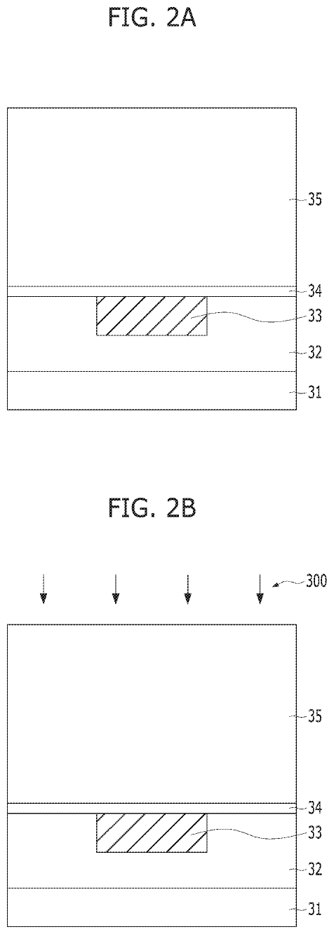

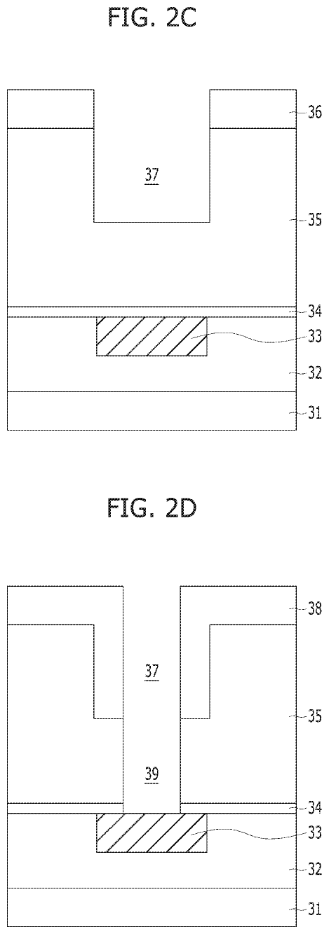

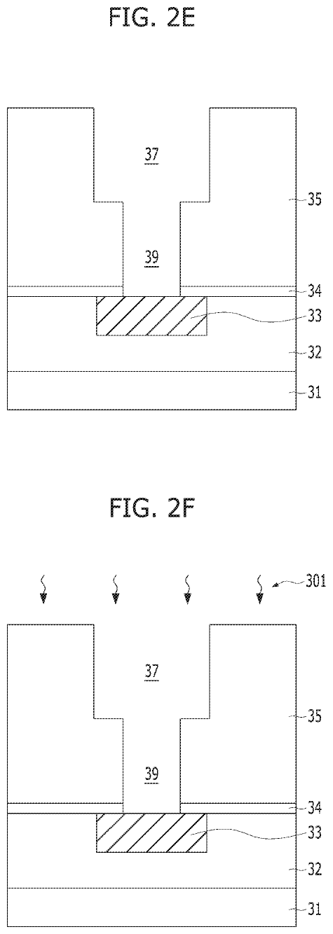

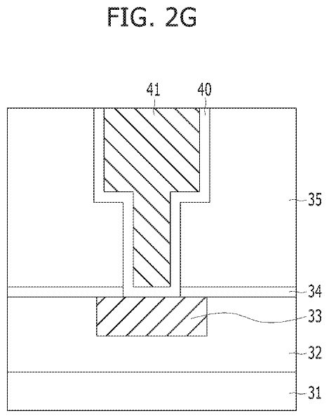

The process of implanting the carbon-containing material into the TEOS will be described in detail with reference to FIGS. 2A and 2B below.

Subsequently, a first hard mask 16 and a second hard mask 17 may be stacked over the second dielectric layer 15. In an embodiment, the first hard mask 16 may be formed over the second dielectric layer 15, and the second hard mask 17 may be formed over the first hard mask 16. The first hard mask 16 may be formed directly on the second dielectric layer 15, and the second hard mask 17 may be formed directly on the first hard mask 16. The first and second hard masks 16 and 17 may include a material having an etch selectivity with respect to the second dielectric layer 15. The first and second hard masks 16 and 17 may include a material that may be easily removed. The first and second hard masks 16 and 17 may be formed of materials having different etch selectivities. For example, the first hard mask 16 may include Tetra Ethyl Ortho Silicate (TEOS), and the second hard mask 17 may include Spin On Carbon (SOC).

An opening may be opened by the first and second hard masks 16 and 17. The opening defined by the first and second hard masks 16 and 17 may overlap with the first metal line 13.

Referring to FIG. 1B, a trench 18 may be formed by etching the second dielectric layer 15 which is exposed by the first and second hard masks 16 and 17. The trench 18 may be a region where a second metal line is formed. The trench 18 may be formed by etching the second dielectric layer 15 to a predetermined depth. In the etching process for forming the trench 18, the etching surface of the second dielectric layer 15 may be damaged. As a result, part of the carbon contained in the second dielectric layer 15 may be lost. According to the carbon loss of the surface of the trench 18, that is, the carbon loss of the surface of the second dielectric layer 15 forming the trench 18, the dielectric constant of the surface of the second dielectric layer 15 may increase. Also, although not illustrated, a damage layer may be formed on the surface of the trench 18 by the etching.

Referring to FIG. 1C, the second hard mask 17 (see FIG. 1B) may be removed. The first hard mask 16 may not be removed due to its different etch selectivity, but may remain over the second dielectric layer 15 intact.

Subsequently, a carbon-containing material implantation process 100 may be performed onto the second dielectric layer 15. The carbon-containing material implantation process 100 may serve to suppress an increase in the dielectric constant of the surface of the second dielectric layer 15 caused by the trench 18 forming process shown in FIG. 1B. When a damage layer (not shown) is formed on the surface of the trench 18 in the above-described etching process, the damage layer may serve as a sacrificial layer during the carbon-containing material implantation process 100. Although not illustrated, the damage layer may be removed through a cleaning process or the like after the carbon-containing material implantation process 100 is completed.

In the carbon-containing material implantation process 100, the carbon-containing material may include carbon. The carbon-containing material implantation process 100 may include an ion implantation process. A carbon tilt ion implantation may be performed as the carbon-containing material implantation process 100. The first hard mask 16 may serve as a sacrificial layer for protecting the upper surface of the second dielectric layer 15 during the carbon-containing material implantation process 100. Also, when the first hard mask 16 is formed of silicon oxide (e.g., TEOS), the dielectric constant of the first hard mask 16 may be lowered by the carbon-containing material implantation process 100 to form a low-k dielectric layer. Therefore, the process of removing the first hard mask 16 may be omitted.

As a result of the carbon-containing material implantation process 100, a carbon implantation region 15D may be formed on the surface of the trench 18, that is, the surface of the second dielectric layer 15 forming the trench 18. The carbon content of the carbon implantation region 15D may be the same as or higher than the carbon content in the second dielectric layer 15. Therefore, an increase in the dielectric constant of the surface of the second dielectric layer 15 may be suppressed.

Referring to FIG. 1D, a third hard mask 19 may be formed over the first hard mask 16 and the second dielectric layer 15 of the trench 18. The third hard mask 19 may include a material having an etch selectivity with respect to the first hard mask 16 and the second dielectric layer 15. The third hard mask 19 may include a material that may be easily removed. The third hard mask 19 may include, for example, SOC (Spin On Carbon).

Subsequently, the second dielectric layer 15 and the etch stop layer 14 of the bottom surface of the trench 18 exposed by the third hard mask 19 may be etched to form a via 20 that exposes the first metal line 13. The via 20 may serve as a contact for coupling the first metal line 13 and the second metal line (not shown). The width of the via 20 may be formed narrower than the width of the trench 18. The carbon implantation region 15D of the side wall and a part of the bottom surface of the trench 18 may be protected by the third hard mask 19 without being exposed.

Referring to FIG. 1E, the third hard mask 19 (see FIG. 1D) may be removed. Accordingly, a dual damascene structure formed of the via 20 and the trench 18 having different widths may be formed in the second dielectric layer 15. In an embodiment, in the damascene structure of the via 20 and the trench 18, the trench 18 may be wider than the via 20 and the via may be positioned centrally below the trench 18 as shown in FIG. 1F.

Subsequently, a heat treatment 101 of the second dielectric layer 15 may be performed. The heat treatment 101 may be performed for curing the etched surface of the second dielectric layer 15. For example, the heat treatment 101 may be performed in an atmosphere of hydrogen or nitrogen. The surfaces of the trench 18 and the via 20, that is, the exposed surface of the second dielectric layer 15 which forms the trench 18 and the via 20 may be cured by the heat treatment 101. Once heat treated, the carbon implantation region 15D (see FIG. 1C) may be referred to as a carbon recovery region 15R.

Referring to FIG. 1F, a second metal line 22 may be formed to fill the via 20 and the trench 18. A barrier layer 21 may be formed between the second metal line 22 and the second dielectric layer 15.

The second metal line 22 may be formed by a series of process steps including first forming the barrier layer 21 on the profile of the exposed surface of the second dielectric layer 15 in the via 20 and the trench 18, then forming a conductive material to fill the remainder of via 20 and the trench 18, and finally etching the conductive material and the barrier layer 21 so that the upper surface of the second dielectric layer 15 is exposed. Herein, the process of etching the conductive material and the barrier layer 21 may be performed by a Chemical Mechanical Polishing (CMP) process or an etch-back process. Once the process is completed the top surface of the second metal line 22 may be coplanar with the top surface of the second dielectric layer 15.

The barrier layer 21 may serve to prevent diffusion of the second metal line 22 into the second dielectric layer 15 and the carbon recovery region 15R. The barrier layer 21 may be formed of at least one material selected among Ta, TaN, TiN, WN and W—Si—N. The second metal line 22 may include, for example, tungsten, copper or aluminum.

In this embodiment of the present invention, when the second metal line 22 is formed, the first hard mask 16 (see FIG. 1E) is removed simultaneously as the second metal line is formed. But the subsequent process may be performed without removing the first hard mask 16 (see FIG. 1E).

FIGS. 2A to 2G are cross-sectional views illustrating a method for fabricating a semiconductor device in accordance with another embodiment of the present invention.

Referring now to FIG. 2A, a first dielectric layer 32 in which a first metal line 33 is buried may be formed over a semiconductor substrate 31.

The semiconductor substrate 31 may be a semiconductor substrate in which a lower structure (not shown) such as a gate, a bit line, and a capacitor is formed. The semiconductor substrate 31 may be formed of a material containing silicon. The semiconductor substrate 31 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The semiconductor substrate 31 may include a group TIT/V semiconductor substrate, for example, a compound semiconductor substrate such as GaAs. The semiconductor substrate 31 may include a silicon on insulator (SOT) substrate.

The first dielectric layer 32 may be formed of a low-k material including silicon oxide, silicon nitride, or a silicon carbon and boron.

The first metal line 33 may include a conductive material. The first metal line 33 may include a metal material. The first metal line 33 may include, for example, tungsten, copper or aluminum.

Subsequently, an etch stop layer 34 may be formed over the first dielectric layer 32 including the first metal line 33. The etch stop layer 34 may also serve as a barrier to prevent diffusion of the first metal line 33. The etch stop layer 34 may include, for example, silicon nitride or silicon carbon.

Subsequently, a second dielectric layer 35 may be formed over the etch stop layer 34. The second dielectric layer 35 may be formed directly on the etch stop layer 34, The second dielectric layer 35 may be a dielectric layer having a low dielectric constant (i.e., a low-k dielectric layer). The second dielectric layer 35 may be of a dielectric material having a lower dielectric constant than a silicon oxide layer (SiO₂), and preferably a material whose dielectric constant is approximately 3.5 or less. The second dielectric layer 35 may be a low-k dielectric layer containing carbon. The second dielectric layer 35 may be organosilicate glass (OSG) containing approximately 1% to 30% carbon. The second dielectric layer 35 may be, for example, SiCOH. SiCOH is a mixture of Si—C—O—H, and may be a material having a characteristic that its dielectric constant decreases as the film contains more hydrogen (H) or carbon (C), which are atoms having small electrical polarizability.

According to another embodiment of the present invention, the second dielectric layer 35 may include silicon oxide capable of lowering the dielectric constant by carbon ion implantation. For example, the second dielectric layer 35 may include (TEAS) Tetra Ethyl Ortho Silicate.

Referring to FIG. 2B, a process 300 of implanting a carbon-containing material into the second dielectric layer 35 may be performed.

Before the carbon-containing material implantation process 300 is performed, a sacrificial layer (not shown) may be formed over the second dielectric layer 35. The sacrificial layer (not shown) may serve to protect the upper surface of the second dielectric layer 35 during the carbon-containing material implantation process 300. The sacrificial layer (not shown) may be formed at a low temperature to prevent changes in the film properties of the second dielectric layer 35. The sacrificial layer (not shown) may include a low-temperature oxide. For example, the sacrificial layer (not shown) may include ULTO (Ultra Low Temperature Oxide). According to another embodiment of the present invention, the sacrificial layer (not shown) may include a low-temperature oxide capable of being formed with a low thickness. According to yet another embodiment of the present invention, the sacrificial layer (not shown) may include a nitride.

The carbon-containing material implantation process 300 may include an ion implantation process. In the carbon-containing material implantation process 300, the carbon-containing material may include carbon. The carbon-containing material implantation process 300 may be performed onto a target in which the implanted carbon may be evenly distributed in the film during the subsequent heat treatment. For example, the carbon-containing material implantation process 300 may be performed with Rp (projection range) of approximately 1500 Å to 2000 Å, but the present invention is not limited thereto, and it may be adjusted according to the thickness of the second dielectric layer 35.

The carbon-containing material injection process 300 may be performed with different carbon implantation concentrations according to the type of the second dielectric layer 35. The carbon-containing material implantation process 300 may adjust the carbon implantation concentration so that when the second dielectric layer 35 is a low-k dielectric layer containing carbon, the amount of carbon lost in the subsequent etching process may be compensated for. According to another embodiment of the present invention, when the second dielectric layer 35 is formed of TEOS, the carbon-containing material implantation process 300 may adjust the carbon implantation concentration to a greater extent than when the second dielectric layer 35 is a low-k dielectric layer containing carbon. That is, when the second dielectric layer 35 is formed of TEOS, the dielectric constant of the second dielectric layer 35 itself may be reduced by increasing the carbon implantation concentration.

Subsequently, a sacrificial layer (not shown) may be removed. Therefore, it is possible to prevent a problem that scattering of the light source occurs during the subsequent patterning due to the damage of the surface or morphology of the sacrificial layer by the carbon-containing material implantation process 300. According to another embodiment of the present invention, without removing the sacrificial layer (not shown), it may be removed together in a subsequent Chemical Mechanical Polishing (CMP) process for forming metal lines.

Referring to FIG. 2C, a first hard mask 36 may be formed over the second dielectric layer 35. The first hard mask 36 may include a material having an etch selectivity with respect to the second dielectric layer 35. The first hard mask 36 may include a material that may be easily removed. For example, the first hard mask 36 may include Spin On Carbon (SOC). According to another embodiment of the present invention, the first hard mask 36 may include a stacked structure of hard masks having different etch selectivities. For example, the first hard mask 36 may include a stacked structure of TEOS (Tetra Ethyl Ortho Silicate) and Spin On Carbon (SOC).

An opening may be opened by the first hard mask 36. The opening defined by the first hard mask 36 may overlap with the first metal line 33.

Subsequently, the second dielectric layer 35 exposed by the first hard mask 36 may be etched to form a trench 37. The trench 37 may be a region where a second metal line is formed, and the trench 37 may be formed by etching the second dielectric layer 35 to a predetermined depth. In the etching process for forming the trench 37, the etched surface of the second dielectric layer 35 may be damaged, and thus carbon contained in the second dielectric layer 35 may be partially lost. According to the carbon loss of the surface of the trench 37, that is, the carbon loss of the surface of the second dielectric layer 35 forming the trench 37, the dielectric constant of the second dielectric layer 35 may increase. However, it is possible to prevent the dielectric constant of the second dielectric layer 35 from increasing by keeping the carbon-containing material implanted into the second dielectric layer 35 through the carbon-containing material implantation process of FIG. 2B at a uniform carbon concentration in the second dielectric layer 35 through a subsequent heat treatment. This will be described in detail when the heat treatment is described below.

According to another embodiment of the present invention, after the trench 37 is formed, a carbon-containing material implantation process may be additionally performed on the surface of the trench 37 as illustrated in FIG. 1C.

Referring to FIG. 2D, the first hard mask 36 (see FIG. 2C) may be removed.

Subsequently, a second hard mask 38 may be formed over the second dielectric layer 35 including the trench 37. The second hard mask 38 may include a material having an etch selectivity with respect to the second dielectric layer 35. The second hard mask 38 may include a material that may be easily removed. The second hard mask 38 may include, for example, Spin On Carbon (SOC).

Subsequently, the second dielectric layer 35 and the etch stop layer 34 of the bottom surface of the trench 37 exposed by the second hard mask 38 may be etched to form a via 39 exposing the first metal line 33. The via 39 may serve as a contact for coupling the first metal line 33 with the second metal line (not shown). The width of the via 39 may be formed narrower than the width of the trench 37. The sidewall and bottom surface of the trench 37 may be protected by the second hard mask 38 to prevent further damage to the second dielectric layer 35 and the carbon loss resulting from the further damage of the second dielectric layer 35.

Referring to FIG. 2E, the second hard mask 38 (see FIG. 2D) may be removed. Accordingly, a dual damascene structure formed of the via 39 and the trench 37 having different widths may be formed in the second dielectric layer 35. In an embodiment, in the damascene structure of the via 39 and the trench 37, the trench 37 may be wider than the via 39 and the via may be positioned centrally below the trench 37 as shown in FIG. 1F.

Referring to FIG. 2F, a heat treatment 301 may be performed on the second dielectric layer 35. The heat treatment 301 may be performed to cure the etched surface of the second dielectric layer 35. For example, the heat treatment, may be performed in the atmosphere of hydrogen or nitrogen. The surfaces of the trench 37 and the via 39, that is, the surface of the second dielectric layer 35 forming the trench 37 and the via 39 may be cured by the heat treatment 301. Also, at the same time, since the carbon implanted into the second dielectric layer 35 in FIG. 2B is uniformly distributed in the second dielectric layer 35, the increase in the dielectric constant resulting from the carbon loss caused by the damage to the second dielectric layer 35 may be suppressed.

Referring to FIG. 2G, a second metal line 41 filling the via 39 and the trench 37 may be formed. A barrier layer 40 may be formed between the second metal line 41 and the second dielectric layer 35.

The second metal line 41 may be formed by a series of process steps including first forming a barrier layer 40 over the profile of the second dielectric layer 35 including the via 39 and the trench 37, forming a conductive material filling the via 39 and the trench 37 over the barrier layer 40, and then etching the conductive material and the barrier layer 40 in such a manner that the upper surface of the second dielectric layer 35 is exposed. Herein, the process of etching the conductive material and the barrier layer 40 may be performed by a Chemical Mechanical Polishing (CMP) process or an etch-back process. When a process of removing the sacrificial layer (not shown) is not performed after the carbon-containing material implantation process shown in FIG. 2B, the sacrificial layer may be removed together in the process of etching the conductive material and the barrier layer 40. Once the process is completed the top surface of the second metal line 41 may be coplanar with the top surface of the second dielectric layer 35.

The barrier layer 40 may serve to prevent diffusion of the second metal line 41 into the second dielectric layer 35. The barrier layer 40 may be formed of at least one material selected among Ta, TaN, TiN, WN and W—Si—N. The second metal line 41 may include, for example, tungsten, copper or aluminum.

According to embodiments of the present invention, the dielectric constant of a dielectric layer may be decreased through an implantation process of a carbon-containing material, and the reliability of the semiconductor device may be improved by suppressing an increase in the dielectric constant of the dielectric layer caused by etching damage.

While the present invention has been described with respect to specific embodiments, it will be apparent to those skilled in the art that various changes and modifications may be made without departing from the spirit and scope of the invention as defined in the following claims.

What is claimed is:

1. A method for fabricating a semiconductor device, comprising:
forming a low-k dielectric layer;
forming a pattern by etching the low-k dielectric layer; and
implanting a carbon-containing material into a surface of the pattern.

2. The method of claim 1, wherein the implanting of the carbon-containing material into the surface of the pattern includes:
a carbon tilt ion implantation process.

3. The method of claim 1, further comprising:
performing a heat treatment onto the low-k dielectric layer, after the implanting of the carbon-containing material into the surface of the pattern.

4. The method of claim 3, wherein the heat treatment is performed in an atmosphere of hydrogen or nitrogen.

5. The method of claim 1, wherein the forming of the low-k dielectric layer includes:
forming a dielectric layer; and
forming the low-k dielectric layer by implanting a carbon-containing material into the dielectric layer to reduce a dielectric constant of the dielectric layer.

6. The method of claim 1, wherein the dielectric layer includes silicon oxide or carbon-containing silicon oxide.

7. A method for fabricating a semiconductor device, comprising:
forming a low-k dielectric layer containing carbon;
forming a trench by performing a first etching of the low-k dielectric layer;
implanting a carbon-containing material into a surface of the trench; and
forming a via by performing a second etching of the low-k dielectric layer on a bottom surface of the trench.

8. The method of claim 7, wherein the implanting of the carbon-containing material into the surface of the trench includes:
a tilt ion implantation process.

9. The method of claim 7, wherein the low-k dielectric layer includes carbon-containing silicon oxide.

10. A method for fabricating a semiconductor device, comprising:
forming a dielectric layer;
implanting a carbon-containing material into the dielectric layer;
forming a trench by a first etching of the dielectric layer containing carbon; and
forming a via by a second etching of the carbon-containing dielectric layer on a bottom surface of the trench.

11. The method of claim 10, further comprising:
performing a heat treatment, after the forming of the via.

12. The method of claim 10, further comprising:
forming a sacrificial layer over the dielectric layer, after the forming of the dielectric layer.

13. The method of claim 10, wherein the dielectric layer includes silicon oxide or carbon-containing silicon oxide.

14. A semiconductor device, comprising:
a first conductive layer formed over a substrate;
a low-k dielectric layer including a trench and a via that are formed over the first conductive layer;
a second conductive layer buried in the trench and the via; and
a carbon implantation region formed on a surface of the trench of the second conductive layer in contact with the second conductive layer.

15. The semiconductor device of claim 14, wherein the low-k dielectric layer includes carbon-containing silicon oxide.

16. The semiconductor device of claim 14, wherein a carbon content of the carbon implantation region is equal to or greater than a carbon content of the low-k dielectric layer.

17. A semiconductor device, comprising:
a low-k dielectric layer formed over a substrate;
an opening formed in the low-k dielectric layer by etching using a hard mask; and
a carbon recovery region formed in the low-k dielectric by implanting a carbon-containing material into a surface region of the low-k dielectric layer pattern that is exposed by the opening.
